(19) United States
(12) Patent Application Publication
(10) Pub. No.: US 2014/0034362 A1
(43) Pub. Date: Feb. 6, 2014

(54) PRINTED CIRCUIT BOARD WITH AN INSULATED METAL SUBSTRATE

(71) Applicants: Emmanuel Talon, Verneuil Sur Seine (FR); Dominique Dupuis, Billericay (GB); François Machet, Poissy (FR)

(72) Inventors: Emmanuel Talon, Verneuil Sur Seine (FR); Dominique Dupuis, Billericay (GB); François Machet, Poissy (FR)

(73) Assignee: VALEO SYSTEMES DE CONTROLE MOTEUR, Cergy Saint Christophe (FR)

(21) Appl. No.: 13/996,681

(22) PCT Filed: Dec. 22, 2011
(86) PCT No.: PCT/FR11/53144

§ 371 Date: Oct. 18, 2013

(30) Foreign Application Priority Data
Dec. 23, 2010 (FR) 1061107

(51) Int. Cl. H05K 1/05; H05K 1/02

(52) U.S. Cl. CPC H05K 1/05; H05K 1/021
USPC 174/252

(57) ABSTRACT

The invention relates to a printed circuit board (1) with an insulated metal substrate, comprising a metal carrier (2), an insulating layer (4) and a metal layer (3) on which at least one electronic component (5) is mounted in at least one mounting zone (3A) of the metal layer (3), characterized in that each mounting zone (3A) is a raised zone of the metal layer (3).

The subject of the present invention is a printed circuit board with an insulated metal substrate.

A printed circuit board is a carrier, generally a sheet, allowing a set of electronic components to be electrically connected to one another with the aim of producing a complex electronic circuit. Printed circuit boards are also referred to as electronic cards.

The rest of the description is devoted to printed circuit boards with insulated metal substrates.

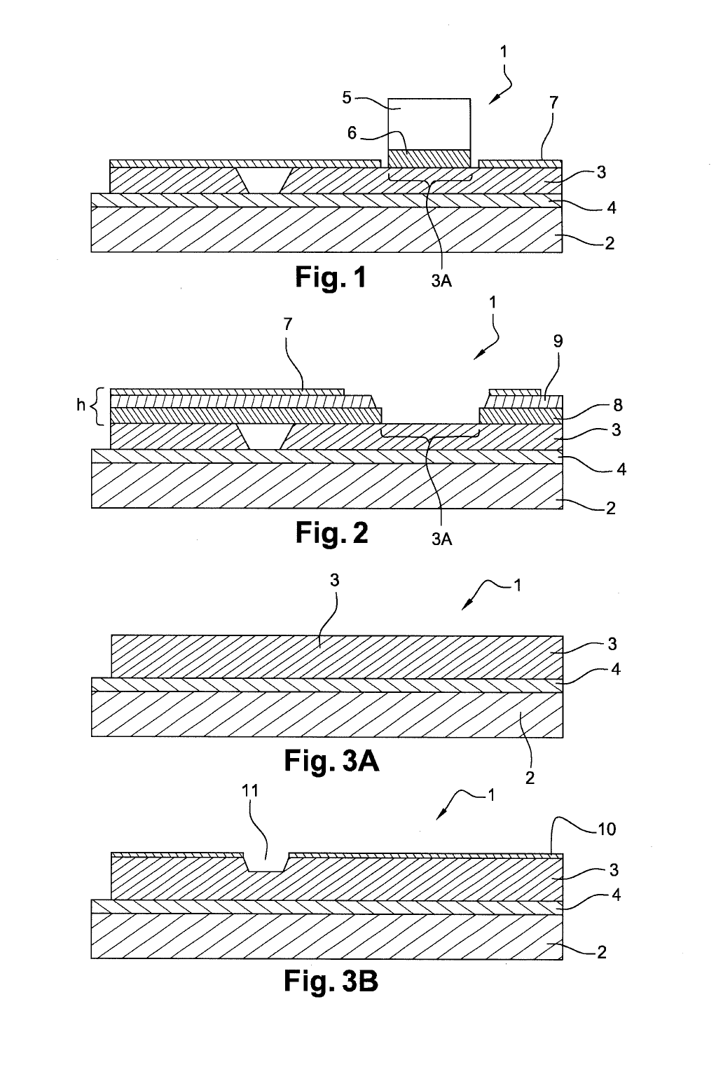

A printed circuit board 1 with an insulated metal substrate, such as illustrated in FIG. 1, comprises a metal carrier 2, typically a copper or aluminum sheet, copper tracks 3 formed in a layer of a copper film, and on which electronic components 5 are mounted via a solder layer 6, and an insulator 4 separating the metal carrier 2 from the copper tracks 3. The insulator 4 is typically an epoxy resin. Electronic components 5 are mounted on the copper tracks 3 in mounting zones 3A of the copper tracks 3.

The copper tracks 3 are conventionally obtained by screen printing. The zones corresponding to the desired tracks are masked, then a chemical or electrolytic bath is applied.

Next, a finishing step is carried out which may comprise preparing the mounting zones 3A for the soldering, and the deposition of a lacquer layer 7 that protects the tracks 3 from oxidation and possible short-circuits.

The structure obtained is a printed circuit board with an insulated metal substrate comprising a layer of copper tracks.

It is also possible to manufacture a printed circuit board 1 with an insulated metal substrate comprising two layers of copper tracks, such as illustrated in FIG. 2, in which elements that are identical to those in FIG. 1 have been given the same reference numbers.

After the first bath, which defines the desired tracks 3, a dielectric layer 8 is selectively deposited on the various zones of the mounting zones 3A. Next, a second copper layer 9 is deposited on the dielectric layer 8, then optionally a lacquer layer 7.

Thus, in the mounting zone 3A there is a height difference h, called an elevation, between the surface of the first copper tracks 3 and the surface of the lacquer layer 7. This elevation h defines a cavity into which solder is placed, intended to ensure mechanical and electrical connection between the copper tracks 3 and the electronic components.

A problem may arise when the solder layer is too thick. Specifically, if the solder layer is too thick, for example greater than 150 μm in thickness, problems arise from the point of view of the quality of the solder, making soldering more difficult.

The present invention aims to overcome these drawbacks.

In particular, it provides a printed circuit board with an insulated metal substrate allowing effective soldering of electronic components to copper tracks.

Thus, one subject of the invention is a printed circuit board with an insulated metal substrate, comprising a metal carrier, an insulating layer and a metal layer on which at least one electronic component is mounted in at least one mounting zone of the metal layer.

According to the invention, each mounting zone is a raised zone of the metal layer.

Thus, as the mounting zone is raised, it is possible to employ a thinner solder layer, thereby making the solder joint more reliable, in particular when the mounting zone is encircled by layers in elevation relative to the first layer of metal tracks, such as for example in a printed circuit board with more than two layers of metal tracks.

The printed circuit board may comprise a solder layer between each mounting zone and the electronic component mounted on said mounting zone.

The invention may be applied to a mounting zone formed in a lower metal track level and surrounded by an upper metal track level.

In particular, the mounting zone may be a zone of a lower metal layer, the mounting zone being surrounded by a dielectric layer placed on the lower metal layer, and an upper metal layer placed on the dielectric layer.

The printed circuit board may comprise:
a first metal layer equipped with at least one raised mounting zone;
a dielectric layer placed on the first metal layer on separate zones of the mounting zone, on either side of the mounting zone; and
a second metal layer placed on the dielectric layer, on either side of the raised mounting zone.

The upper surface of each mounting zone may be located at a height between the height of the upper surface of the dielectric layer and the height of the upper surface of the second metal layer.

Each metal layer may comprise one or more tracks.

Each metal layer may be a copper layer.

Other features and advantages of the present invention will become more clearly apparent on reading the following description given by way of nonlimiting illustration and with reference to the appended drawings, in which:

FIG. 1, described above, illustrates a printed circuit board with an insulated metal substrate comprising a layer of metal tracks, according to the prior art;

FIG. 2, described above, illustrates a printed circuit board with an insulated metal substrate comprising two layers of metal tracks, according to the prior art; and

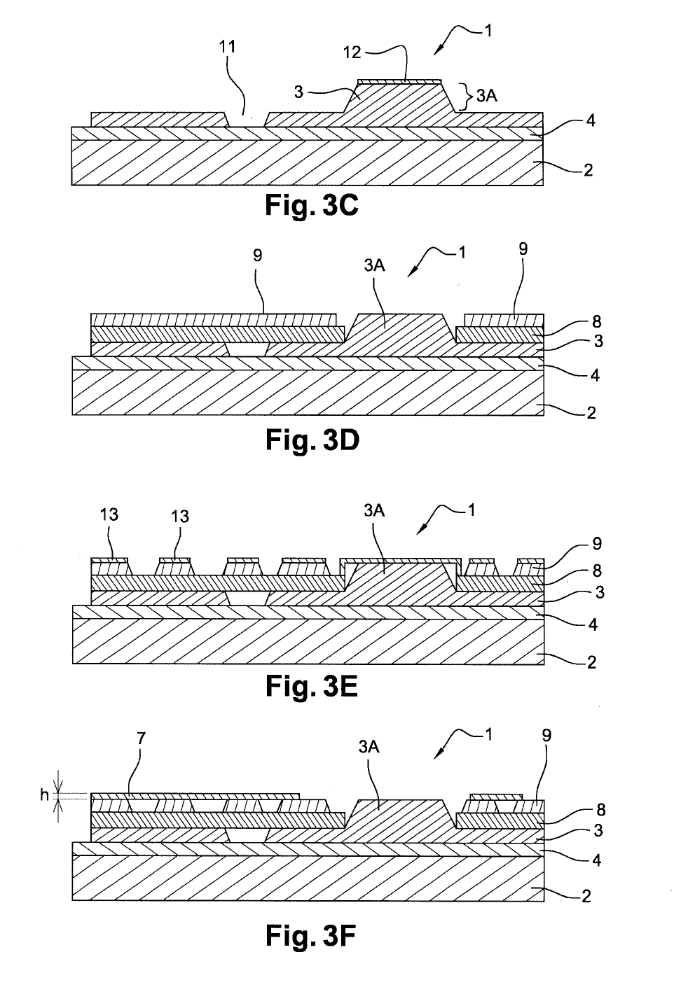

FIGS. 3A to 3F illustrate various steps in a process for manufacturing a printed circuit board according to the invention.

FIG. 3A illustrates a printed circuit board 1 before the screen-printing step, the printed circuit board 1 being equipped with a copper carrier 2 covered with an insulating layer 4 intended to insulate the carrier 2 from a first substantially flat copper layer 3 in which copper tracks will be formed.

A masking layer 10 is then placed on the copper sheet 3. Zones corresponding to the desired tracks are thus masked, then a first bath is applied in order to begin forming a trench 11 in the first copper layer 3 (FIG. 3B).

In a second step, a mounting zone intended to receive an electronic component is masked using a masking layer 12, then a second bath is applied allowing the etching of the trench 11 to be finished and the raised mounting zone 3A to be formed (FIG. 3C). The mounting zone 3A may have a trapezoidal cross section.

Next, as illustrated in FIG. 3D, a dielectric layer 8 is selectively deposited on the copper tracks 3, on either side of the raised mounting zone 3A, a second copper layer 9 then being deposited, also on either side of the mounting zone 3A.

Next, the second thickness of tracks 9 is etched using masks 13 (FIG. 3E), a final lacquer layer 7 then being deposited (FIG. 3F). The surface of the mounting zone 3A is thus substantially on the same level as the surface of the second layer of copper tracks 9, for example lying slightly below the surface of the copper tracks 9.

The process finishes with a soldering step intended to solder an electronic component on the mounting zone 3A. The solder layer is conventionally about 150 μm in thickness. The solder layer may be deposited by screen printing using a stencil. By virtue of the mounting zone 3A that protrudes from the copper layer 3, the final elevation h is decreased, thereby making it possible to obtain a solder layer having a thickness of 150 μm, despite the elevation of the insulator layer 8 and the second copper layer 9. Thus, the soldering of the electronic component to the copper track 3 is improved.

The metal (or first metal) layer 3, which comprises the mounting zone 3A, is a layer in which metal tracks are formed. This may, in particular, be seen in FIGS. 3C to 3F, in which a trench 11 separates the track comprising the mounting zone 3A from another track. For example, the first metal layer comprises metal tracks allowing electrical currents to be transmitted, such as in electronic routing.

The metal carrier 2 is a thermal mass allowing the heat produced by the circuit 1 to be dissipated.

1. A printed circuit board with an insulated metal substrate, comprising:
a metal carrier;
an insulating layer; and
a metal layer on which at least one electronic component is mounted in at least one mounting zone of the metal layer,
wherein each mounting zone is a raised zone of the metal layer.

2. The printed circuit board as claimed in claim 1, further comprising a solder layer between each mounting zone and the electronic component mounted on said mounting zone.

3. The printed circuit board as claimed in claim 1, wherein the mounting zone is a zone of a lower metal layer, the mounting zone being surrounded by a dielectric layer placed on the lower metal layer, and an upper metal layer placed on the dielectric layer.

4. The printed circuit board as claimed in claim 1, further comprising:
a first metal layer equipped with at least one raised mounting zone;
a dielectric layer placed on the first metal layer on separate zones of the mounting zone, on either side of the mounting zone; and
a second metal layer placed on the dielectric layer, on either side of the mounting zone.

5. The printed circuit board as claimed in claim 3, wherein the upper surface of each mounting zone is located at a height between a height of the upper surface of the dielectric layer and a height of the upper surface of the second metal layer.

6. The printed circuit board as claimed in claim 1, wherein each metal layer comprises one or more tracks.

7. The printed circuit board as claimed in claim 1, wherein each metal layer is a copper layer.
